(19) United States
(12) Patent Application Publication
(10) Pub. No.: US 2014/0357200 A1
(43) Pub. Date: Dec. 4, 2014

(54) Method and Apparatus for Controlling Parameters of an Antenna Tuner

(71) Applicant: Broadcom Corporation, Irvine, CA (US)

(72) Inventors: Seppo Olavi ROUSU, Oulu (FI); Juha Pentti Tapio VALTANEN, Oulu (FI); Ville JUHOLIN, Oulu (FI)

(73) Assignee: Broadcom Corporation, Irvine, CA (US)

(21) Appl. No.: 14/291,797

(22) Filed: May 30, 2014

(30) Foreign Application Priority Data
Jun. 4, 2013 (GB) 1309953.6

(51) Int. Cl. H04B 1/40; H03H 7/40; H04B 1/10

(52) U.S. Cl. CPC H04B 1/40; H04B 1/1027; H03H 7/40
USPC 455/77

(57) ABSTRACT

The present invention discloses a control method, an apparatus and a computer program for antenna tuner parameters of a radio transceiver. The updating moments of the antenna tuner parameters are selected depending on predominant interference status in the receiver. Based on the sensed interference level, an update decision is made whether the external interference is below a selected threshold value. The parameter change is executed only in low interference situations. In high interference levels (low SIR), the antenna tuner parameters are calculated but they are not enforced in the antenna tuner. The control process for updating the antenna tuner parameters is continuous in given time intervals.

### FIELD OF THE INVENTION

The present invention relates to a method and apparatus for controlling parameters of an antenna tuner. At least some embodiments of the invention relate to mobile communication networks, and especially to antenna tuning for transmitters and receivers applied in different radio access technologies where potential interferences exist, like in e.g. Long Term Evolution (LTE) networks, device to device communication, public safety networks, ad hoc networks, etc.

### DESCRIPTION OF THE RELATED ART

The purpose of an antenna tuner is to match the impedance of the transceiver to the impedance of the antenna so that in different use scenarios of the terminal, the impedance is matched as well as possible between the antenna and the transceiver front end. The load impedance seen from the antenna tuner may significantly change due to e.g. by a touching or a closely locating part of a body of a mobile phone user or some other object. The antenna tuner therefore compensates this environmental effect. In prior art, the antenna tuner has been created in a form of an electrical RLC circuit (comprising resistors, coils and capacitors; with varying or fixed component values) with varying structures, or by a circuit comprising two variable capacitors. In case the antenna tuner does not work properly in a given time instant, i.e. the impedance matching is poor (the impedances differ with great extent), it results in reflections of the transmitted signal back towards the transmitter, therefore requiring more input power in order to achieve a desired radiated TX power at the antenna.

Radio transmission environment usually comprises different kinds of sources which must be taken into account when receiving a particular transmission. FIG. 1 illustrates an example of a radio transmission and reception environment comprising different kinds of radio transceivers. The radio transceiver system comprises a WLAN (short range Wireless Local Area Network) transceiver, a cellular radio transceiver and a transceiver under examination which comprises a transmitter and a receiver front end (FE), together with an antenna tuner. In the transmitter RF signal path, the last element is a power amplifier (PA), generating desired TX power level to be fed to the antenna. In the receiving side, the first module to process the signal is the LNA, low-noise amplifier, which magnifies the received signal which usually has low amplitude levels.

As shown in FIG. 1, detection circuitry with couplers can be implemented between the antenna tuner and the front end, detecting actual signal levels of forward and reverse signals. The radio environment in this example comprises also external radio signal sources, shown in FIG. 1 as a WLAN transceiver and a cellular transceiver. These transceivers represent external interference sources. The WLAN, device-to-device (D2D) and cellular signal sources in the right side of the figure are here regarded as internal interferences. Furthermore, D2D communication radio may be an internal and/or external interference source.

A problematic situation emerges from the interfering signals coming from other radio signal sources to the receiver under consideration.

In more detail, interfering signals may comprise any fundamental signal of an interfering transmitter, power level of an adjacent frequency band of a fundamental signal, power level of an adjacent frequency channel of a fundamental signal, wideband noise from any source, any harmonic component of an interfering signal, adjacent channel power of such a harmonic signal (=harmonic ACLR power; Adjacent Channel Leakage Ratio), and intermodulation results, for example.

The isolation between an interfering radio and the victim radio has a significant effect in case they locate galvanically connected among each other like shown with the three transceivers of the “Radio apparatus” in FIG. 1. Isolation between the interference source and the target radio may be changed by at least one of following: performing changes in antenna environment, altering mechanical dimensions of the terminal, altering antenna directivity, altering antenna aperture gain, or changing the distance between antennas or TX and/or RX antenna port location(s).

The transceiver does not have capability to separate internal and external interference signals among the detected signals. The control logic simply makes the decisions based on the summed signal and applies control signals accordingly.

Patent publication WO 2004/110088 discusses a way of improving the receiver performance in interfering conditions. In case an interfering signal hits the receiving band, a processor determines a timing pattern for the detected interference, by taking into account the timing information of own transmitted signals. The processor manipulates those signals which are received during the same time intervals; more precisely, the Automatic Gain Control (AGC) module of the receiver takes into account the GSM timing advance which is the same for the interfering source and the receiver acting as a victim.

Therefore, there is a need for an efficient algorithm for controlling an antenna tuner when external interferences are present because the interference signals coupled to the detector circuitry of the target transceiver further affect the circuitry which controls the antenna tuner. As a result from a misinterpreted detected signal, a wrong control signal (wrong parameters) would be generated for the antenna tuner, which would further lead to a mismatch between the antenna and the transceiver, severely affecting e.g. the transmitted radiated power from the antenna, and thus, weakening the connection quality or increasing the needed power supply in vain in such a situation.

### BRIEF DESCRIPTION OF THE DRAWINGS

The accompanying drawings, which are included to provide a further understanding of the invention and constitute a part of this specification, illustrate embodiments of the invention and together with the description help to explain the principles of the invention. The examples shown in the drawings are not the only possible embodiments of the invention and the invention is not considered to be limited to the presented embodiments. In the drawings:

FIG. 1 illustrates an embodiment of a radio apparatus environment, comprising interfering external radio transceivers, and functional parts of the target radio transceiver,

FIG. 2a illustrates antenna tuner parameter change principle as an exemplary flow chart,

FIG. 2b illustrates the interference detection functionality in more detail as an exemplary flow chart,

FIG. 3a illustrates a more detailed functional structure of the radio transceiver comprising an antenna tuner, the structure comprising an oscillator (VCO), and

FIG. 3b illustrates a more detailed functional structure of the radio transceiver comprising an antenna tuner but without an oscillator.

### DETAILED DESCRIPTION

According to an aspect of the present invention, there is provided a method for controlling parameters of an antenna tuner of a transceiver. The method comprises measuring a forward RF signal and a reverse RF signal of the transceiver; detecting an external interfering signal level in the reverse RF signal; making a parameter update decision by a calculation algorithm when the detected interfering signal level is below an interference threshold value; calculating new parameters for the antenna tuner which parameters would optimize impedance matching between the antenna and the transceiver in case the parameters would be in force; and updating the parameters of the antenna tuner to the calculated parameters when the parameter update decision is in force.

In an embodiment of the invention, the calculation algorithm comprises the steps of demodulating the reverse RF signal coherently; correlating the demodulated signal to a known transmitted signal; calculating a difference between the demodulated signal and the known transmitted signal; obtaining a merit of similarity from the correlating and calculating steps; and triggering the parameter update decision when the merit of similarity indicates that no significant interference has been detected.

In an embodiment, the method further comprises using the previous parameter values in the antenna tuner in case the results of the calculation algorithm diverge.

In an embodiment, the method further comprises recognizing a source or type of the detected external interfering signal from its pattern and/or strength; and gathering time dependency information of the detected external interfering signal based on the recognized source or type.

In an embodiment, the method further comprises determining in the recognizing step whether the detected external interfering signal is a time-division duplex signal; a frequency-division duplex signal; a device-to-device signal; an industrial, scientific and medical (ISM) band signal; a leaked signal from an adjacent frequency band; a harmonic component of a signal source; or an intermodulation distortion result of several signal sources.

In an embodiment, the method further comprises updating the parameters of the antenna tuner immediately after the parameter update decision has been made, or at a specifically set later time instant.

In an embodiment, the method further comprises subtracting an interfering signal part from a total received signal, resulting in a payload signal; and calculating the optimal parameters for the antenna tuner based on the payload signal.

In an embodiment, the method further comprises calculating the effect of the updated antenna tuner parameters in the system if the calculated optimal parameters are used.

In an embodiment, the detection of the external interfering signal level in the reverse RF signal is performed through signal-to-interference-ratio estimation which is performed through autocorrelation analysis of the I/Q signals.

According to another aspect of the invention, there is provided an apparatus for controlling parameters of an antenna tuner of a transceiver. The apparatus comprises a memory; and control logic which is configured to measure a forward RF signal and a reverse RF signal of the transceiver; detect an external interfering signal level in the reverse RF signal; make a parameter update decision by a calculation algorithm when the detected interfering signal level is below an interference threshold value; calculate new parameters for the antenna tuner which parameters would optimize impedance matching between the antenna and the transceiver in case the parameters would be in force; and update the parameters of the antenna tuner to the calculated parameters when the parameter update decision is in force.

The apparatus comprising the control logic and the calculation algorithm is configured to perform the same method steps as disclosed above.

In an embodiment of the apparatus, the measurement and the detection are configured to be performed by a detection circuitry connected to the transceiver front end through at least one directional coupler.

According to yet another aspect of the invention, a computer program for controlling parameters of an antenna tuner of a transceiver, is presented. The computer program comprises code which is adapted to perform the following steps, when executed on a data-processing system:

measuring a forward RF signal and a reverse RF signal of the transceiver;

detecting an external interfering signal level in the reverse RF signal;

making a parameter update decision by a calculation algorithm when the detected interfering signal level is below an interference threshold value;

calculating new parameters for the antenna tuner which parameters would optimize impedance matching between the antenna and the transceiver in case the parameters would be in force; and

updating the parameters of the antenna tuner to the calculated parameters when the parameter update decision is in force.

In an embodiment, the computer program is embodied in a computer readable medium.

It is possible to combine one or more of the embodiments and aspects disclosed above to form one or more further embodiments of the present invention.

Reference will now be made in detail to the embodiments of the present invention, examples of which are illustrated in the accompanying drawings.

The present invention introduces a method, an apparatus and a computer program for controlling antenna tuner controls of a transceiver.

The antenna tuner is needed to compensate an antenna mismatch situation in different operational conditions, like when a body part of a user touches or is in close proximity to the antenna and thus affects the impedance of the antenna and creates impedance mismatch between the antenna and the RF front end of the transceiver. The above issues apply also to any other objects being in close proximity of the antenna instead of a user body part.

The present invention discusses which kind of control signals are applied to the antenna tuner and when and how frequently (including variable intervals) to tune these control signals.

In an aspect of the present invention, a control algorithm for an antenna tuner of a radio transceiver experiencing notable external interference is introduced. Such a control algorithm can also be called an antenna tuner algorithm. The control algorithm takes interfering signals into account in a way where the antenna will be matched with the front end circuitry as well as possible even in cases when notable external interference levels are detected. Furthermore, the control algorithm will take into account any physical contact or close proximity of a user body part regarding the antenna of the terminal. Furthermore, the control algorithm is capable of recognizing what is the possible type or source of a detected interfering signal. Possible interference sources or types or forms of an interfering RF signal are a TDD (time-division duplex) signal, an FDD (frequency-division duplex) signal, a narrow band signal, a wide band signal, a continuous wave signal, a modulated signal, public safety communication signal, a D2D communication signal, a ISM band (WLAN) signal or a cellular telecommunication signal (like signals sent by a base station, relay or femtocell) or a harmonic component of any of these. Furthermore, possible interference sources or types may be also ACLR (Adjacent Channel Leakage Ratio) power or intermodulation results. For interpreting this issue in a broad manner, the terminal can use an own network ID versus geographical location of the UE. It is also possible to gather data e.g. from the cloud about possible radio communication systems or transmitters which may create interfering signals (like fundamental signals, harmonics and intermodulation distortion components) at the geographical location of the UE.

In an embodiment of the invention, the algorithm detects the received signal in a periodical manner, and it deduces those instants of time when a pre-set interference amplitude or power level is exceeded among the detected received signal.

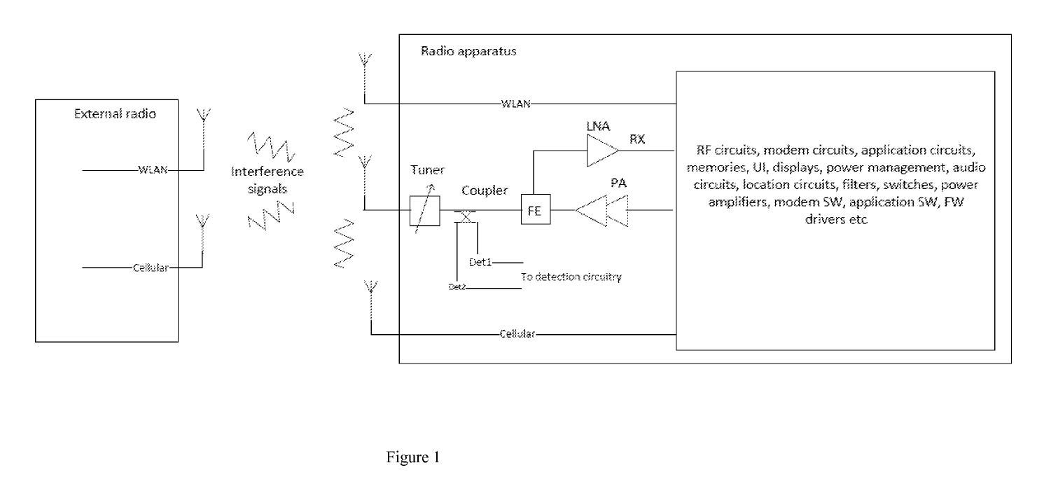

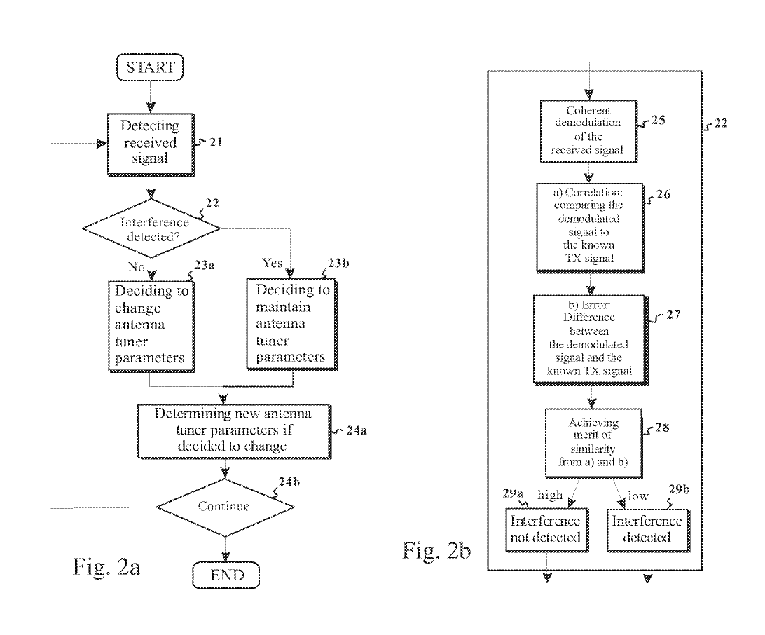

The main principles of the invented control algorithm are shown in FIGS. 2a and 2b in the form of flow charts. A first embodiment of the antenna tuner control algorithm is shown in FIG. 2a. At a first step of the algorithm, signals are received by the antenna of an observed transceiver and through a directional coupler or some other coupling arrangement, and the received signal is detected in the observed transceiver 21. The detection can be implemented by a dedicated detection circuitry (shown in FIG. 1) which is wired between the RF front end components of the transceiver and the control logic. The detection circuitry is connected to the RF signal path via one or more directional coupler(s), capacitor(s) or inductor(s). In an embodiment, the directional coupler or couplers locate between the antenna tuner and the front end but the coupler may be implemented also inside a certain module or component, or between any two components within the transceiver. The directional coupler may even be realized through a capacitive connection.

In the following step of the algorithm, the presence of external interference is examined for the detected signal in step 22, which is described more precisely by a flow chart of FIG. 2b.

At first in the interference detection of FIG. 2b, the received signal is coherently demodulated into a baseband signal; coherent meaning that the carrier signal used in the demodulation is synchronized in frequency and phase with the carrier used in the TX modulator. This signal shows the intended transmitted signal but additionally, all interfering components are summed onto the intended signal. On the other hand, the system possesses the knowledge of the plain TX signal form in the baseband. In an embodiment, this signal may be guided through the directional coupler from a forward (TX) signal. Therefore, correlation 26 needs to be figured out, meaning the comparison between the received demodulated signal pattern and the known TX signal pattern. The correlating phase 26 results in achieving an error pattern where the error data is “sampled” as a function of time in a form of a symbol pattern in step 27; meaning the difference between the demodulated signal and the known TX signal. The error pattern 27 shows interferential signal forms as a function of time. At the next step 28, a merit of similarity is achieved from the correlation and error steps 26 and 27. In case the correlation is high (closer to 1), it is deduced that no significant interference has been detected 29a during the time period under examination. However, in case the correlation is low (closer to 0), the control logic determines that interference indeed exists and it exceeds a tolerable level 29b specified for the system and the application. Regarding this step, a parameter called a correlation threshold value can be specified to be used in the control logic. In case the correlation is lower than the correlation threshold value, interference is decided to exist in the system 29b. Otherwise, when the correlation is over the correlation threshold value, it is decided that no significant external interference is present in the transceiver 29a.

Going back to FIG. 2a, the antenna tuner parameters are decided to be updated or maintained regarding the deduced interference status at each considered time period. If the control logic has made a decision that no notable interference is currently present 29a, the antenna tuner parameters are decided to be controlled (changed if needed) in a normal manner 23a. However, in case notable interference is determined to exist in the received signal 29b, the antenna tuner parameters are decided to be maintained the same (kept fixed) 23b until the interference situation changes notably.

In step 24a, new parameters of the antenna tuner, which optimize the antenna's impedance matching with the transceiver front end in the current physical and functional situation, are determined if the decision to change them has been made in step 23a. The determination can be performed e.g. through a calculation of tunable component values or through an iterative calculation algorithm. The physical and functional situation means taking into account the possibly varying impedance of the antenna due to e.g. user hand effects. All calculations are here based on the fact that the complex impedance of the antenna should equal the complex impedance of the transceiver front end, resulting in minimal or lack of reflecting signal components in this interface.

The changes in the parameters of the antenna tuner can be made immediately after an interference free time slot, or at a specifically set later time instant. In an embodiment, the antenna tuner is an RLC (comprising resistors, coils and/or capacitors) impedance matching circuit with at least one variably tune-able component, whose value(s) can be changed at any given time instant. In case the decision to maintain the parameters has been made 23b in the current iteration round, the step 24a will leave the antenna tuner parameters as they were.

After changing or maintaining the antenna tuner parameters in step 24a, the algorithm is set to continue 24b and start from the beginning 21. The time period used in a single iteration round can be selected freely.

It is possible to vary the order of the steps in FIG. 2a without departing from the essence of the invention. For example, the step 24a (the determination of the antenna tuner parameters) can be performed right after the received signal detection 21. After the parameter calculation, the system will decide in steps 22-23 whether to take these calculated parameters into use in order to maintain uplink and/or downlink quality parameters in predefined limits or predefined margins. When new calculated parameters are taken into use, the changing of parameters may need to be done in more than one parameter adjustment step, in order to avoid decreasing link quality due to too large phase shift in communication link signals due to too large parameter change in one instant.

In another embodiment of the invention, after the control logic has decided that there indeed exists notable interference, the control logic manipulates the received signal in a way where the interfering signal part is subtracted from the total received signal. The result is the pure payload signal. The subtraction can be made e.g. through filtering in case it lies on a different frequency band than the payload signal. The payload signal can thereafter be used as a basis for controlling the antenna tuner parameters like “in no-interference situation” earlier. When the interference disappears from the receiving signal pattern, the antenna's impedance matching will be immediately at its optimum regardless of the physical environment of the antenna surroundings (like physical contact by the user to the antenna).

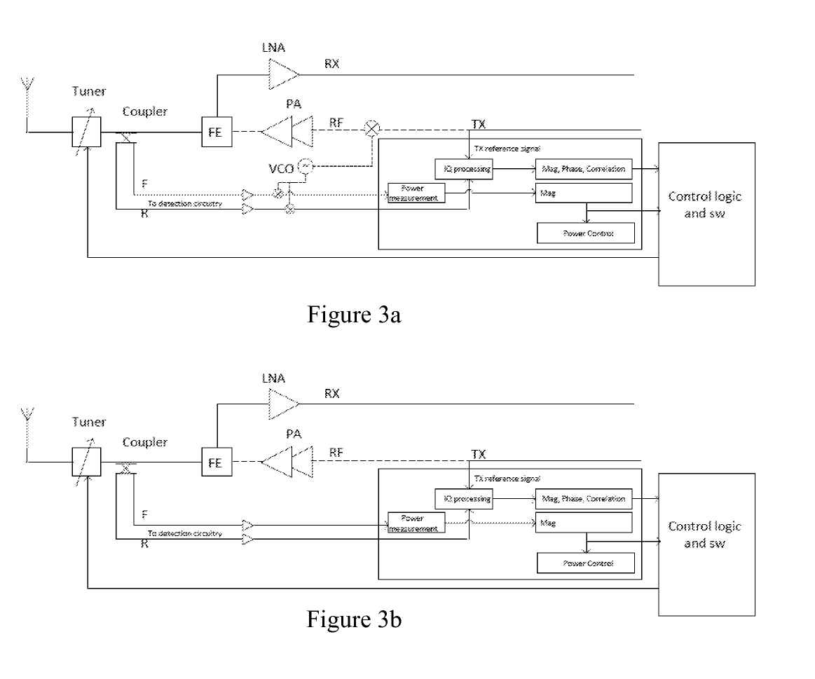

FIG. 3a illustrates a system where the method according to the invention can be implemented. The basic structure of the transmitting and receiving signal processing elements are the same as in FIG. 1. The elements comprise the antenna, the antenna tuner, signal coupler or couplers, the front end comprising the low-noise amplifier (LNA) as the first amplifier in the RX signal chain, and the power amplifier (PA) as the last amplifying element in the TX signal chain. Furthermore, the voltage-controlled oscillator (VCO) supplies the signal needed in the conversion between the RF signal and the base band signal. The forward and reverse power signals detected just beside the antenna tuner unit are amplified and converted into base band detection signals. The forward (TX) power is measured in the “Power measurement” unit, giving the magnitude “Mag”. The power magnitude data naturally acts as a main input for the “Power control” functionality. Furthermore, the reverse RF signal is directed into IQ signal processing where also the TX reference signal is fed in. From I (In-phase) and Q (Quadrature) signal analysis, we achieve the magnitude, phase and correlation information. The correlation 26 of FIG. 2b is thus performed by the “IQ processing” block of FIG. 3a in this embodiment of the invention. The magnitude, phase, and correlation calculation results are fed in the control logic, which applies an own piece of software. The control logic determines the error signal 27 and achieves the merit of similarity 28. Finally, the decision whether significant external interference exists or not, is made by the control logic. The frequency or the time period at hand which is handled in a single calculation round can be also determined as a parameter to the control unit.

When the control logic has decided whether to update the parameters for the antenna tuner based on the interference status in step 22, the parameters are supplied to the antenna tuner to apply them into force. In an alternate embodiment, new or old parameters may be supplied first to antenna tuner and then taken into use with a triggering action.

FIG. 3b illustrates the same structure in a simpler form, without the voltage-controlled oscillator and related wirings. This embodiment thus means that all the signal processing is performed with the RF signals. Otherwise, the calculations and functional units are the same as in FIG. 3a for this embodiment of the invention.

It is noted that the detection of the interfering signal level among the received RF signal can be performed through SIR (signal to interference ratio) estimation which in turn can be performed through autocorrelation analysis of the I/Q signals. In theory, fully random (noise-like) signal samples have an autocorrelation equal to 0. The less noise there exists in the samples together with the useful signal, the higher the autocorrelation will be in the I/Q signals.

The method of detecting the interference level among the signal and making the parameter update decision for the antenna tuner will succeed also in situations where the interference is high enough to “cover” the useful signal. It is also possible to calculate the new parameters for the antenna tuner and its effect on the transceiver's operational ability in such low SIR situations (high interference levels). Finally, it is always possible to go back to the previous or some earlier parameter values in case the algorithm results in parameter values which do not converge.

An advantage of the present invention is that it allows an efficient antenna tuner parameter control algorithm even in the cases where a notably high interfering signal would mess up the proper functioning of the antenna tuner, and even when the human body part touching or being close to the antenna requires an efficient antenna tuning parameter change algorithm for achieving reliable and constantly good quality of communication.

The present invention is also applicable to all 3GPP releases from release onwards, D2D communication and to public safety communication. It can therefore be applied to any currently used and future releases supporting the mixed use of licensed and unlicensed bands in one or more independent carriers and/or carrier aggregation. The invention is also applicable to any other technologies which apply the use of licensed and unlicensed bands in their carrier aggregation processes.

The present invention can be applied to wireless communication terminals which may be mobile phones, smart phones, communicators, public safety devices, consumer electronics devices, USB devices, laptops, finger computers, modem on module, etc. any terminal devices with wireless communication capability. The algorithm can be implemented in a modem of a user terminal or of a device applying wireless communication. In another embodiment, the algorithm may be implemented into a host device memory and a processor, or alternatively it can be loaded from a host device to a modem in power-up steps.

A separate or an embedded control unit may perform the abovementioned method steps where applicable. In an embodiment, the apparatus comprises a memory, and at least one processor or controller is configured to execute applicable method steps according to the invention. Furthermore, the method according to the invention can be implemented with one or several computer programs which can be executed by at least one processor or controller.

In an embodiment, the method steps, apparatus and the computer program according to the invention can be implemented by at least one separate or embedded hardware module for an existing mobile communication system.

The computer program(s) can be stored (embodied) on at least one computer readable medium such as, for example, a memory circuit, memory card, magnetic or optic disk. Some functional entities may be implemented as program modules linked to another functional entity. The functional entities may also be stored in separate memories and executed by separate processors, which communicate, for example, via a message bus or an internal network within the network node. An example of such a message bus is the Peripheral Component Interconnect (PCI) bus.

The exemplary embodiments of the invention can be included within any suitable device, for example, including any suitable servers, workstations, PCs, laptop computers, PDAs, Internet appliances, handheld devices, cellular telephones, wireless devices, consumer electronics, public safety devices, modem on module, system on chip, system on package, other devices, and the like, capable of performing the processes of the exemplary embodiments, and which can communicate via one or more interface mechanisms, including, for example, Internet access, telecommunications in any suitable form (for instance, voice, modem, and the like), wireless communications media, one or more wireless communications networks, cellular communications networks, public safety networks, D2D communication, ad hoc networks, 3G communications networks, 4G communications networks, Public Switched Telephone Network (PSTNs), Packet Data Networks (PDNs), satellite positioning, the Internet, intranets, a combination thereof, and the like.

It is to be understood that the exemplary embodiments are for exemplary purposes, as many variations of the specific hardware used to implement the exemplary embodiments are possible, as will be appreciated by those skilled in the hardware arts. For example, the functionality of one or more of the components of the exemplary embodiments can be implemented via one or more hardware devices.

The exemplary embodiments can store information relating to various processes described herein. This information can be stored in one or more memories, such as a hard disk, optical disk, magneto-optical disk, RAM, and the like. One or more databases can store the information used to implement the exemplary embodiments of the present invention. The databases can be organized using data structures (e.g., records, tables, arrays, fields, graphs, trees, lists, and the like) included in one or more memories or storage devices listed herein. The processes described with respect to the exemplary embodiments can include appropriate data structures for storing data collected and/or generated by the processes of the devices and subsystems of the exemplary embodiments in one or more databases.

All or a portion of the exemplary embodiments can be implemented by the preparation of application-specific integrated circuits or by interconnecting an appropriate network of conventional component circuits, as will be appreciated by those skilled in the electrical arts.

As stated above, the components of the exemplary embodiments can include computer readable medium or memories according to the teachings of the present invention and for holding data structures, tables, records, and/or other data described herein. Computer readable medium can include any suitable medium that participates in providing instructions to a processor for execution. Such a medium can take many forms, including but not limited to, non-volatile media, volatile media, transmission media, and the like. Non-volatile media can include, for example, optical or magnetic disks, magneto-optical disks, and the like. Volatile media can include dynamic memories, and the like. Transmission media can include coaxial cables, copper wire, fiber optics, and the like. Transmission media also can take the form of acoustic, optical, electromagnetic waves, and the like, such as those generated during radio frequency (RF) communications, infrared (IR) data communications, and the like. Common forms of computer-readable media can include, for example, a floppy disk, a flexible disk, hard disk, magnetic tape, any other suitable magnetic medium, a CDROM, CDRW, DVD, any other suitable optical medium, punch cards, paper tape, optical mark sheets, any other suitable physical medium with patterns of holes or other optically recognizable indicia, a RAM, a PROM, an EPROM, a FLASH-EPROM, any other suitable memory chip or cartridge, a carrier wave or any other suitable medium from which a computer can read.

It is obvious to a person skilled in the art that with the advancement of technology, the basic idea of the invention may be implemented in various ways. The invention and its embodiments are thus not limited to the examples described above; instead they may vary within the scope of the claims.

1. A method for controlling parameters of an antenna tuner of a transceiver, comprising:
measuring a forward RF signal and a reverse RF signal of the transceiver;
detecting an external interfering signal level in the reverse RF signal;
making a parameter update decision by a calculation algorithm when the detected interfering signal level is below an interference threshold value;
calculating new parameters for the antenna tuner which would optimize impedance matching between the antenna and the transceiver in case the parameters would be in force; and
updating the parameters of the antenna tuner to the calculated parameters when the parameter update decision is in force.

2. The method according to claim 1, wherein the calculation algorithm comprises the steps of:
demodulating the reverse RF signal coherently;
correlating the demodulated signal to a known transmitted signal;
calculating a difference between the demodulated signal and the known transmitted signal;
obtaining a merit of similarity from the correlating and calculating steps; and
triggering the parameter update decision when the merit of similarity indicates that no significant interference has been detected.

3. The method according to claim 1, further comprising:
using the previous parameter values in the antenna tuner in case the results of the calculation algorithm diverge.

4. The method according to claim 1, further comprising:
recognizing a source or type of the detected external interfering signal from its pattern and/or strength; and
gathering time dependency information of the detected external interfering signal based on the recognized source or type.

5. The method according to claim 4, further comprising:
determining in the recognizing step whether the detected external interfering signal is a time-division duplex signal; a frequency-division duplex signal; a device-to-device signal; an industrial, scientific and medical (ISM) band signal; a leaked signal from an adjacent frequency band; a harmonic component of a signal source; or an intermodulation distortion result of several signal sources.

6. The method according to claim 1, further comprising:
updating the parameters of the antenna tuner immediately after the parameter update decision has been made, or at a specifically set later time instant.

7. The method according to claim 1, further comprising:
subtracting an interfering signal part from a total received signal, resulting in a payload signal; and
calculating the optimal parameters for the antenna tuner based on the payload signal.

8. The method according to claim 7, further comprising:
calculating the effect of the updated antenna tuner parameters in the system if the calculated optimal parameters are used.

9. The method according to claim 1, wherein the detection of the external interfering signal level in the reverse RF signal is performed through signal-to-interference-ratio estimation which is performed through autocorrelation analysis of the I/Q signals.

10. An apparatus for controlling parameters of an antenna tuner of a transceiver, comprising:
a memory;
control logic configured to:
measure a forward RF signal and a reverse RF signal of the transceiver;
detect an external interfering signal level in the reverse RF signal;
make a parameter update decision by a calculation algorithm when the detected interfering signal level is below an interference threshold value;
calculate new parameters for the antenna tuner which would optimize impedance matching between the antenna and the transceiver in case the parameters would be in force; and
update the parameters of the antenna tuner to the calculated parameters when the parameter update decision is in force.

11. The apparatus according to claim 10, wherein the memory comprises the calculation algorithm which is configured to:
demodulate the reverse RF signal coherently;
correlate the demodulated signal to a known transmitted signal;
calculate a difference between the demodulated signal and the known transmitted signal;
obtain a merit of similarity from the correlating and calculating steps; and
trigger the parameter update decision when the merit of similarity indicates that no significant interference has been detected.

12. The apparatus according to claim 10, wherein the control logic is configured to:
use the previous parameter values in the antenna tuner in case the results of the calculation algorithm diverge.

13. The apparatus according to claim 10, wherein the control logic is configured to:
recognize a source or type of the detected external interfering signal from its pattern and/or strength; and
gather time dependency information of the detected external interfering signal based on the recognized source or type.

14. The apparatus according to claim 13, wherein the control logic is configured to determine in the recognizing step whether the detected external interfering signal is a time-division duplex signal; a frequency-division duplex signal; a device-to-device signal; an industrial, scientific and medical (ISM) band signal; a leaked signal from an adjacent frequency band; a harmonic component of a signal source; or an intermodulation distortion result of several signal sources.

15. The apparatus according to claim 10, wherein the control logic is configured to update the parameters of the antenna tuner immediately after the parameter update decision has been made, or at a specifically set later time instant.

16. The apparatus according to claim 10, wherein the control logic is configured to:
subtract an interfering signal part from a total received signal, resulting in a payload signal; and
calculate the optimal parameters for the antenna tuner based on the payload signal.

17. The apparatus according to claim 16, wherein the control logic is configured to calculate the effect of the updated antenna tuner parameters in the system if the calculated optimal parameters are used.

18. The apparatus according to claim 10, wherein the control logic is configured to detect the external interfering signal level in the reverse RF signal through signal-to-interference-ratio estimation which is performed through autocorrelation analysis of the I/Q signals.

19. The apparatus according to claim 10, wherein the measurement and the detection are configured to be performed by a detection circuitry connected to the transceiver front end through at least one directional coupler.

20. A non-transitory computer readable medium comprising a computer program for controlling parameters of an antenna tuner of a transceiver, the computer program comprising code adapted to perform the following steps, when executed on a data-processing system:
measuring a forward RF signal and a reverse RF signal of the transceiver;
detecting an external interfering signal level in the reverse RF signal;
making a parameter update decision by a calculation algorithm when the detected interfering signal level is below an interference threshold value;
calculating new parameters for the antenna tuner which would optimize impedance matching between the antenna and the transceiver in case the parameters would be in force; and
updating the parameters of the antenna tuner to the calculated parameters when the parameter update decision is in force.

21. (canceled)
